(19) United States
(12) Patent Application Publication
(10) Pub. No.: US 2026/0142627 A1
(43) Pub. Date: May 21, 2026

(54) AMPLIFIER CURRENT MEASUREMENT

(71) Applicant: TEXAS INSTRUMENTS INCORPORATED, Dallas, TX (US)

(72) Inventors: Jinlin ZHU, Shanghai (CN); Jianquan LIAO, Shanghai (CN); Ziyang YUAN, Shanghai (CN); Zhi GAO, Yancheng (CN); Weiyu SHEN, Shanghai (CN)

(21) Appl. No.: 18/950,900

(22) Filed: Nov. 18, 2024

(51) Int. Cl. H03F 3/217; G01R 19/10; G01R 19/25

(52) U.S. Cl. CPC H03F 3/217; G01R 19/10; G01R 19/25; H03F 2200/171

(57) ABSTRACT

In some examples, a circuit include a class-D amplifier configured to receive an input signal and provide a drive signal based on and responsive to the input signal for driving an output device. The circuit also includes a current sensing circuit coupled to the class-D amplifier and configured to provide voltage signals representative of current flow through the class-D amplifier. The circuit also includes a current measurement circuit coupled to the current sensing circuit and configured to provide a first and second voltage difference signals derived from the voltage signals. The circuit also includes a current summing circuit coupled to the current measurement circuit and configured to determine a first current signal representative of the first voltage difference signal, determine a second current signal representative of the second voltage difference signal, and combine the first and second current signals to form a current sum signal. The circuit also includes a converter circuit coupled to the current summing circuit and configured to convert the current sum signal to a voltage representation.

### BACKGROUND

Class-D amplifiers are switching based amplifiers that may be implemented in application environments such as automobiles. However, challenges may exist in such application environments due to circuit faults that can occur. Modern circuitry experiences competing interests of increased functionality for decreased cost and size. Thus, challenges may exist in effectively detecting these circuit faults.

### SUMMARY

In some examples, a circuit includes a first amplifier, a current sensing circuit, a current measurement circuit, a current summing circuit, and a converter circuit. The first amplifier includes a first transistor having a control terminal and first and second terminals, the first terminal of the first transistor coupled to a first voltage terminal. The first amplifier also includes a second transistor having a control terminal and first and second terminals, the first terminal of the second transistor coupled to the second terminal of the first transistor, and the second terminal of the second transistor coupled to a second voltage terminal. The current sensing circuit has first, second, third, and fourth inputs, and first, second, third, and fourth outputs. The first input of the current sensing circuit is coupled to the first terminal of the first transistor, the second input of the current sensing circuit is coupled to the control terminal of the first transistor, the third input of the current sensing circuit is coupled to the control terminal of the second transistor, and the fourth input of the current sensing circuit is coupled to the second voltage terminal. The current measurement circuit has first, second, third, fourth, fifth, and sixth inputs and first and second outputs. The first input of the current measurement circuit is coupled to the first output of the current sensing circuit, the second input of the current measurement circuit is coupled to the second output of the current sensing circuit, the third input of the current measurement circuit is coupled to the third output of the current sensing circuit, and the fourth input of the current measurement circuit is coupled to the fourth output of the current sensing circuit. The current summing circuit has first, second, third, and fourth inputs and first, second, and third outputs. The first input of the current summing circuit is coupled to a third voltage terminal, the second input of the current summing circuit is coupled to the second voltage terminal, the third input of the current summing circuit is coupled to the first output of the current measurement circuit, the fourth input of the current summing circuit is coupled to the second output of the current measurement circuit, the first output of the current summing circuit is coupled to the fifth input of the current measurement circuit, and the second output of the current summing circuit is coupled to the sixth input of the current measurement circuit. The converter circuit has first and second inputs and an output. The first input of the converter circuit is coupled to a reference voltage terminal, and the second input of the converter circuit is coupled to the third output of the current summing circuit.

In some examples, a circuit includes a class-D amplifier, a current sensing circuit, a current measurement circuit, a current summing circuit, and a converter circuit. The class-D amplifier is configured to receive an input signal and provide a drive signal based on and responsive to the input signal for driving an output device. The current sensing circuit is coupled to the class-D amplifier and configured to provide first, second, third, and fourth voltage signals representative of current flow through the class-D amplifier. The current measurement circuit is coupled to the current sensing circuit and configured to provide a first voltage difference signal derived from the first and second voltage signals and a second voltage difference signal derived from the third and fourth voltage signals. The current summing circuit is coupled to the current measurement circuit and configured to determine a first current signal representative of the first voltage difference signal, determine a second current signal representative of the second voltage difference signal, and combine the first and second current signals to form a current sum signal. The converter circuit is coupled to the current summing circuit and configured to convert the current sum signal to a voltage representation.

In some examples, a system includes an output device and a driver. The driver includes a first branch that includes an amplifier, a current sensing circuit, a current measurement circuit, a current summing circuit, and a converter circuit. The amplifier is configured to receive an input signal and provide a drive signal based on and responsive to the input signal for driving the output device. The current sensing circuit is coupled to the amplifier and configured to provide first, second, third, and fourth voltage signals representative of current flow through the amplifier. The current measurement circuit is coupled to the current sensing circuit and configured to provide a first voltage difference signal derived from the first and second voltage signals and a second voltage difference signal derived from the third and fourth voltage signals. The current summing circuit is coupled to the current measurement circuit and configured to determine a first current signal representative of the first voltage difference signal, determine a second current signal representative of the second voltage difference signal, and combine the first and second current signals to form a current sum signal. The converter circuit is coupled to the current summing circuit and configured to convert the current sum signal to a voltage representation.

### BRIEF DESCRIPTION OF THE DRAWINGS

FIG. 1 is a block diagram of an example system.

FIG. 2 is a schematic diagram of an example of a driver.

FIG. 3 is a timing diagram of example signals that may be present in the system of FIG. 1.

FIG. 4 is a flowchart of an example method of current measurement in the system of FIG. 1.

FIG. 5 is a diagram of example signals that may be present in the system of FIG. 1.

### DETAILED DESCRIPTION

One application for class-D amplifiers is vehicles, such as automobiles. For example, class-D amplifiers are suitable for implementation in audio application of vehicles, such as a virtual engine sound system (VESS) or acoustic vehicle alerting system (AVAS) of a hybrid or electric vehicle, an audio entertainment system, a notification or alert system, such as may be implemented in an instrument cluster of a vehicle, as a part of an audible communication system of the vehicle, or the like. In some implementations, fault tolerance may be less acceptable than in other implementations. For example, for safety related applications, such as VESS, AVAS, or alert systems, it is useful to detect faults in a class-D amplifier system with limited latency. Faults that may occur can include a short to power, a short to ground, a short across a load (e.g., a speaker), an open across the load, or the like.

Examples of this description provide for high side and low side current sensing in a differential class-D amplifier. In some examples, a current summing circuit sums detected high side and low side current in the class-D amplifier. Summing the current via a current summing circuit may mitigate effects of current mirror mismatch between measurements of the high side current and the low side current. In some examples, linearity of the current summing circuit is increased by reducing drain-to-source voltage swing of components of the current summing circuit, such as by referencing a terminal of the current summing circuit to a non-zero value signal.

In some examples, a switching circuit switches between differential branches of the class-D amplifier. In this way, at a first time, current information of a first differential branch of the class-D amplifier may be obtained and, at a second time, current information of a second differential branch of the class-D amplifier may be obtained. The current information may be captured for both idle or standby states of the amplifier and play or operational states of the amplifier. Based on the idle and play current information, a current sense output signal indicative of a load current may be obtained. In various examples, a processor, controller, or other circuit monitors the current sense output signal to identify and, if appropriate, mitigate faults, such as those identified above. While the current measurement of this description is generally described in the context of class-D amplifiers, it may be applicable to other amplifier types (e.g., class-A amplifier, class-B amplifiers, class-AB amplifiers, or the like) or other circuit or circuit component type.

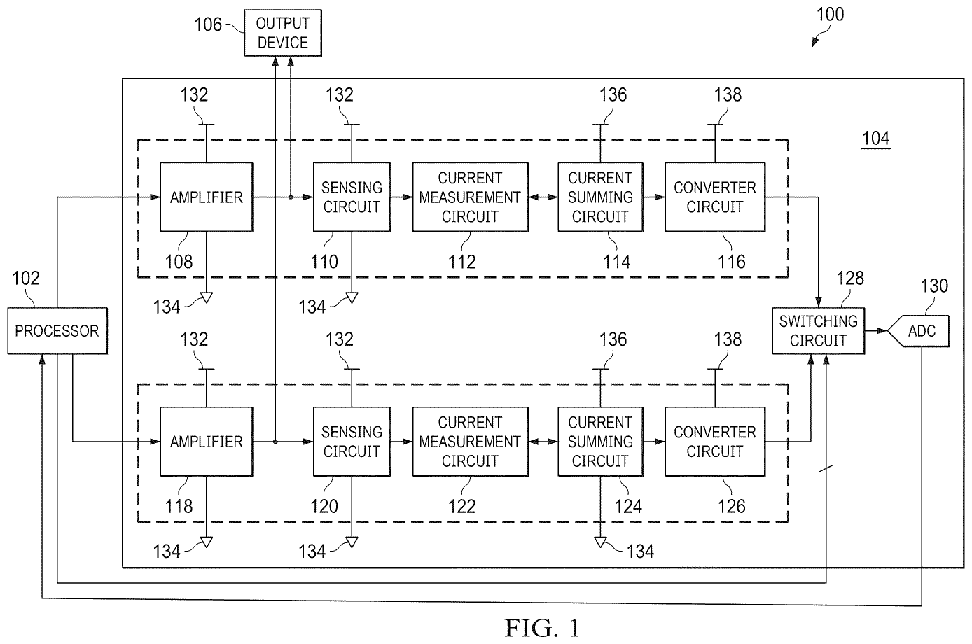

FIG. 1 is a block diagram of an example system 100. In some examples, the system 100 is an audio system which receives an input signal and provides an output signal based on the input signal. The system 100 may be representative of at least a portion of, or may be implemented in, a transportation vehicle such as an automobile, in an electronic device such as a smartphone, a wearable device, an entertainment device, headphones, a media receiver, a television, a speaker system, or the like, or in any other device which receives an input signal and provides an output signal based on the input signal.

In an example, the system 100 includes a processor 102, a driver 104, and an output device 106. For example, some implementations of the driver 104 include an amplifier 108, a current sensing circuit 110, a current measurement circuit 112, a current summing circuit 114, and a converter circuit 116. In some examples, the driver 104 receives a differential signal input and provides a differential signal output such that the driver 104 includes an amplifier 118, a current sensing circuit 120, a current measurement circuit 122, a current summing circuit 124, and a converter circuit 126. The driver 104 may also include a switching circuit 128, and an analog-to-digital converter (ADC) 130. In some examples, the amplifier 108 is a class-D amplifier, the amplifier 118 is a class-D amplifier, and/or the ADC 130 is a successive-approximation ADC (SAR ADC). The driver 104 may be referred to as a class-D driver with current sensing. Collectively, the amplifier 108, current sensing circuit 110, current measurement circuit 112, current summing circuit 114, and converter circuit 116 may be referred to as a first branch of the driver 104 and the amplifier 118, current sensing circuit 120, current measurement circuit 122, current summing circuit 124, and converter circuit 126 may be referred to as a second branch of the driver 104.

In an example architecture of the system 100, the amplifier 108 has first, second, third, and fourth inputs, and has an output. The first input of the amplifier 108 is coupled to a voltage terminal 132. In some examples, a voltage supply (not shown) couples to the voltage terminal 132 to provide a voltage (e.g., a supply voltage) to the amplifier 108. The second input of the amplifier 108 is coupled to a ground terminal 134 at which a ground voltage potential is provided. The ground terminal 134 may also be generally referred to as a voltage terminal at which a voltage is provided having a value less than the voltage provided at the voltage terminal 132. In some examples, that lower valued voltage has a value of a ground voltage potential. In an example, a first input signal is provided at third input of the amplifier 108. In some examples, the first input signal is provided by the processor 102. The output of the amplifier 108 is coupled to a first input of the output device 106. In some examples, the output of the amplifier 108 is coupled to an input of a filter (not shown) having an output coupled to the first input of the output device 106. Although not shown in FIG. 1, in some examples, additional circuits, components, or devices are coupled in a signal chain between the processor 102 and the driver 104, such as between the processor 102 and the amplifiers 108, 118. These circuits may include one or more modulators, one or more additional drivers or power stages, one or more filters, or the like. In an example of the system 100 which include such components in the signal chain between the processor 102 and the driver 104, description herein of the processor 102 providing a signal to the driver 104 (such as to one or both of the amplifiers 108, 118) is understood to include the processor 102 providing the signal through the signal chain including such components. In some examples, a connection as shown or described in this description represents a coupling between an output of one component and an input of another component or represents a coupling between terminals of two or more different components. Moreover, arrows on the connections may represent direction of signal or data flow, e.g., from the output of one component to the input of another component. Connections without an arrow may represent or include a terminal of one or more components coupled to another component to receive a signal or data.

Continuing the example, the current sensing circuit 110 has first, second, third, and fourth inputs, and has first, second, third, fourth, fifth, sixth, and seventh outputs. The first input of the current sensing circuit 110 is coupled to the voltage terminal 132. The second input of the current sensing circuit 110 is coupled to the ground terminal 134. The third input of the current sensing circuit 110 is coupled to the third input of the amplifier 108. The fourth input of the current sensing circuit 110 is coupled to the fourth input of the amplifier 108. The first output of the current sensing circuit 110 is coupled to the output of the amplifier 108.

Continuing the example, the current measurement circuit 112 has first, second, third, fourth, fifth, sixth, seventh, and eighth inputs and has first and second outputs. The first input of the current measurement circuit 112 is coupled to the voltage terminal 132. The second input of the current measurement circuit 112 is coupled to the ground terminal 134. The third input of the current measurement circuit 112 is coupled to the second output of the current sensing circuit 110. The fourth input of the current measurement circuit 112 is coupled to the third output of the current sensing circuit 110. The sixth input of the current measurement circuit 112 is coupled to the fourth output of the current sensing circuit 110. The seventh input of the current measurement circuit 112 is coupled to the fifth output of the current sensing circuit 110.

Continuing the example, the current summing circuit 114 has first, second, third, fourth, fifth, and sixth inputs, and has first, second, and third outputs. The first input of the current summing circuit 114 is coupled to a voltage terminal 136. In some examples, a second voltage supply (not shown) couples to the voltage terminal 136 to provide a second voltage (e.g., a second supply voltage) to the current summing circuit 114. The second input of the current summing circuit 114 is coupled to ground terminal 134. The third input of the current summing circuit 114 is coupled to the first output of the current measurement circuit 112. The fourth input of the current summing circuit 114 is coupled to the second output of the current measurement circuit 112. In some examples, the fifth input of the current summing circuit 114 is coupled to a first bias source (not shown). In some examples, the sixth input of the current summing circuit 114 is coupled to a second bias source (not shown). In some examples, the first bias source provides a first bias voltage (vb1) and the second bias voltage source provides a second bias voltage (vb2). The first output of the current summing circuit 114 is coupled to the fifth input of the current measurement circuit 112. The second output of the current summing circuit 114 is coupled to the eighth input of the current measurement circuit 112.

Continuing the example, the converter circuit 116 has first and second inputs and has an output. The first input of the converter circuit 116 is coupled to a voltage reference terminal 138. In some examples, a voltage reference supply (not shown) couples to the voltage reference terminal 138 to provide a voltage reference to the converter circuit 116. The second input of the converter circuit 116 is coupled to the third output of the current summing circuit 114.

Continuing the example, the switching circuit 128 has first, second, third, and fourth inputs and has an output. The first input of the switching circuit 128 is coupled to the output of the converter circuit 116. The second and fourth inputs of the switching circuit 128 are each coupled to the processor 102. The ADC 130 has an input and an output. The input of the ADC 130 is coupled to the output of the switching circuit 128. The output of the ADC 130 is coupled to the processor 102. In some examples, the output of the ADC 130 is a multi-bit bus through which data is provided in parallel. In other examples, the output of the ADC 130 is a single-bit interface through which data is provided serially.

In some examples, the amplifier 118 has first, second, third, and fourth inputs, and has an output. The first input of the amplifier 118 is coupled to the voltage terminal 132. The second input of the amplifier 118 is coupled to the ground terminal 134. In an example, a second input signal is provided at third input of the amplifier 118 and the fourth input of the amplifier 118. In some examples, the second input signal is provided by the processor 102. In some examples, the second input signal is a logical inversion of the first input signal. In other examples, an inverter circuit (not shown) receives the first input signal from the processor 102 and provides the second input signal. The output of the amplifier 118 is coupled to a second input of the output device 106. In some examples, the output of the amplifier 118 is coupled to an input of a second filter (not shown) having an output coupled to the second input of the output device 106.

Continuing the example, the current sensing circuit 120 has first, second, third, and fourth inputs, and has first, second, third, fourth, fifth, sixth, and seventh outputs. The first input of the current sensing circuit 120 is coupled to the voltage terminal 132. The second input of the current sensing circuit 120 is coupled to the ground terminal 134. The third input of the current sensing circuit 120 is coupled to the third input of the amplifier 118. The fourth input of the current sensing circuit 120 is coupled to the fourth input of the amplifier 118. The first output of the current sensing circuit 120 is coupled to the output of the amplifier 118.

Continuing the example, the current measurement circuit 122 has first, second, third, fourth, fifth, sixth, seventh, and eighth inputs and has first and second outputs. The first input of the current measurement circuit 122 is coupled to the voltage terminal 132. The second input of the current measurement circuit 122 is coupled to the ground terminal 134. The third input of the current measurement circuit 122 is coupled to the second output of the current sensing circuit 120. The fourth input of the current measurement circuit 122 is coupled to the third output of the current sensing circuit 120. The sixth input of the current measurement circuit 122 is coupled to the fourth output of the current sensing circuit 120. The seventh input of the current measurement circuit 122 is coupled to the fifth output of the current sensing circuit 120.

Continuing the example, the current summing circuit 124 has first, second, third, fourth, fifth, and sixth inputs, and has first, second, and third outputs. The first input of the current summing circuit 124 is coupled to the voltage terminal 136. The second input of the current summing circuit 124 is coupled to ground terminal 134. The third input of the current summing circuit 124 is coupled to the first output of the current measurement circuit 122. The fourth input of the current summing circuit 124 is coupled to the second output of the current measurement circuit 122. In some examples, the fifth input of the current summing circuit 124 is coupled to the first bias source (not shown) to receive vb1. In some examples, the sixth input of the current summing circuit 124 is coupled to the second bias source (not shown) to receive vb2. The first output of the current summing circuit 124 is coupled to the fifth input of the current measurement circuit 122. The second output of the current summing circuit 124 is coupled to the eighth input of the current measurement circuit 122.

Continuing the example, the converter circuit 126 has first and second inputs and has an output. The first input of the converter circuit 126 is coupled to the voltage reference terminal 138. The second input of the converter circuit 126 is coupled to the third output of the current summing circuit 114. The third input of the switching circuit 128 is coupled to the output of the converter circuit 126.

In an example of operation of the system 100, the amplifier 108 is configured to receive an input signal, such as from the processor 102 or any other suitable device included in the system 100 (but not shown in FIG. 1) or coupled to the system 100. In some examples, the input signal is a signal representative of audio data, representative of a pattern for controlling a light emitting device, or any other suitable signal in analog or digital form and being representative of any data. In some examples, the input signal is a differential input signal such that it has first and second components which are logical inversions of one another. Based on the received input signal, the amplifier 108 provides an output signal to drive the output device 106. In some examples, the current sensing circuit 110 includes at least some components that are replicas of components of the amplifier 108. For example, the amplifier 108 may include multiple transistors, and the current sensing circuit 110 includes at least some transistors that are replicas (e.g., have the same characteristics) as the transistors of the amplifier 108 or are scaled replicas (e.g., have characteristics that are scaled from the characteristics of the transistors of the amplifier 108). The current sensing circuit 110 may also include components, such as resistors, across which measurements may be taken to determine a current flowing through the resistors, and therefore a current representative of a current flow through the amplifier 108. In this way, the current sensing circuit 110 provides a sensed current in the form of voltage signals measured at each respective terminal of the resistors or other components of the current sensing circuit 110.

The current measurement circuit 112 receives pairs of voltage signals provided by the current sensing circuit, where each pair corresponds to measurements from first and second terminals of a same resistor or other component, and determines voltage difference signals representative of a difference between the voltage signals of a respective pair. In an example, the current measurement circuit 112 drives the current summing circuit 114 according to the voltage difference signals to cause currents proportional to the voltage difference signals to flow through the current summing circuit 114. The current summing circuit 114 combines or sums the currents flowing through the current summing circuit 114 to form a current sum signal proportional to or otherwise representative of a current flowing through the amplifier 108. The converter circuit 116 receives the current sum signal and provides a voltage representation of the current sum signal. In some examples, the converter circuit 116 is, or includes, a low-pass filter. In some examples, the low-pass filter of the converter circuit 114 has a cutoff frequency set to the Nyquist frequency such that the converter circuit 116 functions as an anti-aliasing filter.

Operation of the second branch of the driver 104 may be understood based on the above description of operation of the first branch of the driver 104. Accordingly, such description is not repeated again herein.

In an example, the switching circuit 128 receives the voltage representation of the current sum signal provided by the converter circuit 116, as well as the voltage representation of the current sum signal provided by the converter circuit 126. Based on one or more received control signals, the switching circuit 128 selects from the voltage signal received from the converter circuit 116 or the voltage signal received from the converter circuit 126 to provide as a switched output signal of the switching circuit 128. The control signal(s) may be received from any suitable source, the scope of which is not limited herein. For example, the control signal(s) are received from the processor 102 in some implementations of the system 100. The ADC 130 receives the switched output signal and provides a digital representation of the switched output signal.

In an example, the processor 102 (or any other suitable digital and/or analog circuit or component) receives the switched output signal and performs processing based on the switched output signal. In some examples, based on switching of the switching circuit 128, at a first time the switched output signal is representative of current flowing through the amplifier 108. In such an example, at a second time the switched output signal is representative of current flowing through the amplifier 118.

Based on values of the switched output signal captured at various time and operational states of the system 100, the processor 102 may determine a current sense output for the driver 104. In some examples, the current sense output is representative of current flowing through the driver 104 (e.g., the amplifier 108 and the amplifier 118) at multiple points in time and for multiple operational states. The processor 102 may determine the current sense output by determining a difference between a current flowing through the amplifier 108 at a first time while the driver 104 is driving the output device 106 and a current flowing through the amplifier 108 at a second time while the driver 104 is not driving the output device 106, added with a difference between a current flowing through the amplifier 118 at a third time while the driver 104 is driving the output device 106 and a current flowing through the amplifier 118 at a fourth time while the driver 104 is not driving the output device 106. Based on the determined current sense output for the driver 104, the processor 102 may perform calibration of the driver 104 or otherwise control or modify operation of the driver 104. In some examples, the processor 102 filters the current sense output to obtain direct current (DC) and alternating current (AC) components of the current sense output. The processor 102 may process the current sense output with a low-pass filter to obtain the DC component of the current sense output and may process the current sense output with a high-pass filter to obtain the AC component of the current sense output.

In some examples, based on a value of the determined current sense output, the processor 102 determines whether a fault condition exists in the driver 104, such as an open load, a load short, a short to power, or a short to ground. Responsive to detecting the existence of a fault condition, the processor 102 may take one or more actions, such as controlling the driver 104 or any other component (which may not be shown) to mitigate the existence of the fault condition.

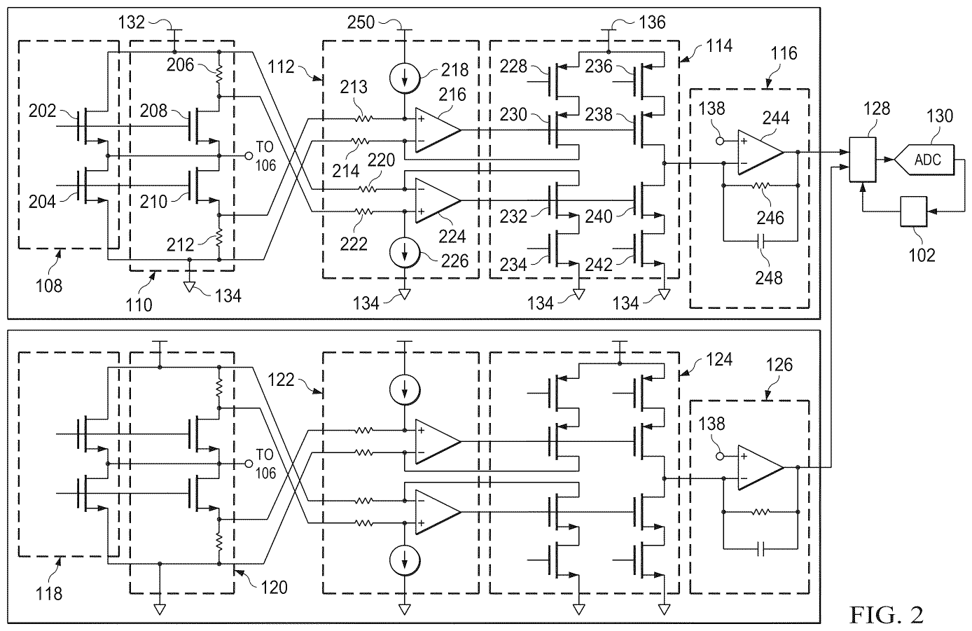

FIG. 2 is a schematic diagram of an example of the driver 104. In FIG. 2, the first branch of the driver 104 is shown in schematic form and the second branch of the driver 104 is shown as a singular block. The second branch of the driver 104 may have a structure substantially similar to that shown in schematic form in FIG. 2 with respect to the first branch of the driver 104, with an exception that the first branch of the driver 104 may receive input signals based on a positive component of a differential signal and the second branch of the driver 104 may receive input signals based on a negative component of the differential signal. Accordingly, a schematic-level description of the second branch of the driver 104 is not repeated again herein.

In an example, the amplifier 108 includes a transistor 202 and a transistor 204. In some examples, the transistor 202 and the transistor 204 together form a class-D amplifier. The current sensing circuit 110 includes a resistor 206, a transistor 208, a transistor 210, and a resistor 212. In some examples, the transistor 208 is a replica (with 1:1 or 1:X ratio) of the transistor 202 and the transistor 210 is a replica (with 1:1 or 1:X ratio) of the transistor 204. The current measurement circuit 112 includes a resistor 213, a resistor 214, an amplifier 216, a current source 218, a resistor 220, a resistor 222, an amplifier 224, and a current source 226. The current summing circuit 114 includes transistors 228, 230, 232, 234, 236, 238, 240, and 242. The converter circuit 116 includes an amplifier 244, a resistor 246, and a capacitor 248. In some examples, the amplifier 244, resistor 246, and capacitor 248 coupled as shown in FIG. 2 form an anti-aliasing, or low-pass, filter.

In an example architecture of the driver 104 of FIG. 2, the transistor 202 has a control terminal and first and second terminals. The first terminal of the transistor 202 is coupled to the voltage terminal 132. The transistor 204 has a control terminal and first and second terminals. The first terminal of the transistor 204 is coupled to the second terminal of the transistor 202 and the second terminal of the transistor 204 is coupled to the ground terminal 134. In an example, the output device 106 coupled to the second terminal of the transistor 202 directly, or through a filter (not shown). The resistor 206 has first and second terminals. The first terminal of the resistor 206 is coupled to the voltage terminal 132. The transistor 208 has a control terminal and first and second terminals. The first terminal of the transistor 208 is coupled to the second terminal of the resistor 206, the second terminal of the transistor 208 is coupled to the second terminal of the transistor 202, and the control terminal of the transistor 208 is coupled to the control terminal of the transistor 202. The first terminal of the transistor 210 is coupled to the second terminal of the transistor 208, and the control terminal of the transistor 210 is coupled to the control terminal of the transistor 204. The resistor 212 has first and second terminals. The first terminal of the resistor 212 is coupled to the second terminal of the transistor 210 and the second terminal of the resistor 212 is coupled to the ground terminal 134.

The resistors 213, 214 each have first and second terminals. The first terminal of the resistor 213 is coupled to the first terminal of the resistor 212. The first terminal of the resistor 214 is coupled to the second terminal of the resistor 212. The amplifier 216 has first and second inputs and an output. The first input of the amplifier 216 is coupled to the second terminal of the resistor 213. The second input of the amplifier 216 is coupled to the second terminal of the resistor 214. The current source 218 has first and second terminals. The first terminal of the current source 218 is coupled to a voltage terminal 250, which in some examples is coupled to a same voltage supply as couples to the voltage terminal 136, or in other examples is coupled to any other suitable voltage supply. The second terminal of the current source 218 is coupled to the first input of the amplifier 216. The resistors 220, 222 each have first and second terminals. The first terminal of the resistor 220 is coupled to the first terminal of the resistor 206. The first terminal of the resistor 220 is coupled to the second terminal of the resistor 206. The amplifier 224 has first and second inputs and an output. The first input of the amplifier 224 is coupled to the second terminal of the resistor 220. The second input of the amplifier 224 is coupled to the second terminal of the resistor 222. The current source 226 has first and second terminals. The first terminal of the current source 226 is coupled to the second input of the amplifier 224. The second terminal of the current source 226 is coupled to the ground terminal 134.

The transistors 228, 230, 232, 234, 236, 238, 240, and 242 each have first and second terminals and control terminals. The first terminal of the transistor 228 is coupled to the voltage terminal 136 and the control terminal of the transistor 228 is coupled to the first bias source (not shown) to receive vb1. In some examples, vb1 is an internally generated (e.g., generated within the driver 104 or system 100) signal to bias the transistor 228 such that the transistors 228, 230 (and correspondingly transistors 236, 238) form a cascode structure or architecture, increasing performance of the current summing circuit 114. The first terminal of the transistor 230 is coupled to the second terminal of the transistor 228, the second terminal of the transistor 230 is coupled to the second input of the amplifier 216, and the control terminal of the transistor 230 is coupled to the output of the amplifier 216. The first terminal of the transistor 232 is coupled to the first input of the amplifier 224, and the control terminal of the transistor 232 is coupled to the output of the amplifier 224. The first terminal of the transistor 234 is coupled to the second terminal of the transistor 232, the second terminal of the transistor 234 is coupled to the ground terminal 134, and the control terminal of the transistor 234 is coupled to the second bias source (not shown) to receive vb2. In some examples, vb2 is an internally generated (e.g., generated within the driver 104 or system 100) signal to bias the transistor 234 such that the transistors 234, 232 (and correspondingly transistors 242, 240) form a cascode structure or architecture, increasing performance of the current summing circuit 114. The first terminal of the transistor 236 has a first terminal coupled to the voltage terminal 136, and the control terminal of the transistor 236 is coupled to the control terminal of the transistor 228. The first terminal of the transistor 238 is coupled to the second terminal of the transistor 236, and the control terminal of the transistor 238 is coupled to the control terminal of the transistor 230. The first terminal of the transistor 240 is coupled to the second terminal of the transistor 238, and the control terminal of the transistor 240 is coupled to the control terminal of the transistor 232. The first terminal of the transistor 242 is coupled to the second terminal of the transistor 240, the second terminal of the transistor 242 is coupled to the ground terminal 134, and the control terminal of the transistor 242 is coupled to the control terminal of the transistor 234.

The amplifier 244 has first and second inputs and an output. The first input of the amplifier 244 is coupled to the voltage reference terminal 138. The resistor 246 has first and second terminals. The first terminal of the resistor 246 is coupled to the output of the amplifier 244 and the second terminal of the resistor 246 is coupled to the second input of the amplifier 244. The capacitor 248 has first and second terminals. The first terminal of the capacitor 248 is coupled to the output of the amplifier 244 and the second terminal of the capacitor 248 is coupled to the second input of the amplifier 244. In an example, the output of the amplifier 244 is coupled to the first input of the switching circuit 128.

In an example of operation of the driver 104 of FIG. 2, input signals provided at the respective control terminals of the transistors 202, 204 are opposite in value. Responsive to a value of an input signal received at its control terminal having a logical high value (e.g., a value of digital “1”), the transistors 202, 204 become conductive in a forward direction between their respective first and second terminals. Conversely, responsive to a value of an input signal received at its control terminal having a logical low value (e.g., a value of digital “0”), the transistors 202, 204 become substantially non-conductive in the forward direction between their respective first and second terminals. Thus, responsive to an input signal of the amplifier 108 having a logical high value, the transistor 202 becomes conductive, providing a signal to the output device having a value approximately equal to a value of a voltage provided at the voltage terminal 132. Conversely, responsive to the input signal of the amplifier 108 having a logical low value, the transistor 204 becomes conductive, providing a signal to the output device having a value approximately equal to a value of the ground voltage potential provided at the ground terminal 134.

As described above, in some examples, fault conditions can occur in the driver 104, such as a short across the transistor 202, a short against the transistor 204, a short across terminals of the output device 106, an open across the transistor 202, and/or an open across the transistor 204. Based on these fault conditions, a current flowing through one or both of the transistors 202, 204 may be altered. To detect these current, the transistors 208, 210 are implemented as replica devices of the transistors 202, 204, respectively. In this way, a current flowing through the transistor 208 flows through the resistor 206 and a current flowing through the transistor 210 flows through the resistor 212. By detecting voltage drops across the resistors 206, 212, information regarding current flow through the transistors 208, 210, and therefore representative of current flow through the transistors 202, 204, may be determined.

For example, the amplifier 216 determines a voltage difference signal representative of a voltage drop across the resistor 212 and the amplifier 224 determines a voltage difference signal representative of a voltage drop across the resistor 206. Each of the voltage difference signals is representative of (e.g., proportional to) current flow through the transistors 202, 204.

In an example, the amplifier 216 drives the transistors 230, 238 to cause a current flowing through the transistors 230, 238 to be proportional to a value of the voltage difference signal provided by the amplifier 216. Similarly, the amplifier 224 drives the transistors 232, 240 to cause a current flowing through the transistors 232, 240 to be proportional to a value of the voltage difference signal provided by the amplifier 224. Thus, a sum of currents flowing through the transistors 238, 240 is provided at the drain of the transistor 238 as a current sum signal. This current sum signal is representative of an overall current flow through the amplifier 108 (e.g., the transistors 202, 204). The amplifier 244 is arranged in a low-pass architecture such that the amplifier 244 converts the current sum signal into a voltage representation and provides anti-aliasing (e.g., filtering) of the current sum signal in forming the voltage representation.

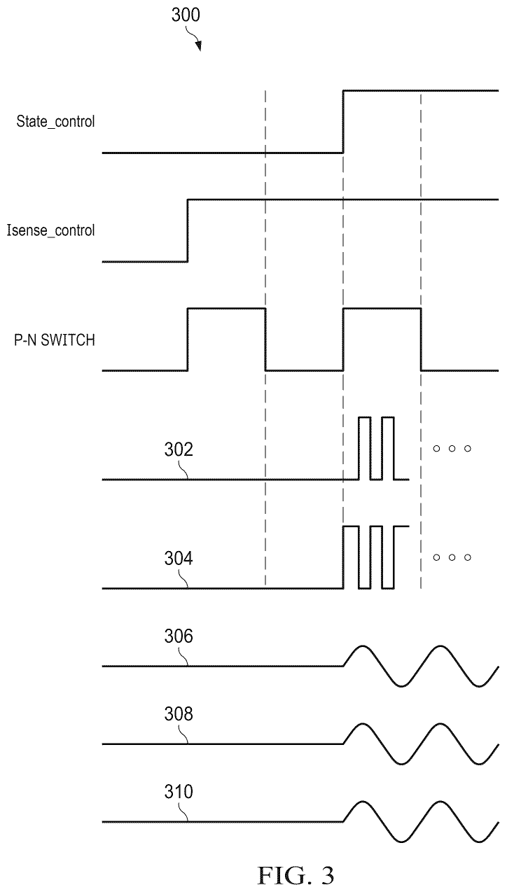

FIG. 3 is a timing diagram 300 of example signals that may be present in the system 100. Although certain signals are shown in the diagram 300, in some examples at least some of the signals may be omitted from the system 100 and/or other signals not shown in the diagram 300 are present in the system 100. The diagram 300 includes a state control signal (State_control) which represents an operational mode, or state, of the system 100. For example, when the driver 104 is not driving the output device 106, State_control has a logical low value indicating that the driver 104 is in an idle mode or state. Similarly, when the driver 104 is driving the output device 106, State_control may have a logical high value indicating that the driver 104 is in play mode or state. The diagram 300 also includes an current sensing control signal (Isense_control) which indicates whether current sensing and measurement of the driver 104, such as described above herein, is enabled or disabled. For example, responsive to Isense_control having a logical high value, current sensing and measurement of the driver 104 is enabled. Conversely, responsive to Isense_control having a logical low value, current sensing and measurement of the driver 104 is disabled. The diagram 300 also includes a switching signal (P-N switch) indicative of which voltage representation, of the first branch or the second branch of the driver 104, is provided to the ADC 130 for conversion to a digital representation. For example, responsive to P-N switch having a logical high value, the voltage representation of the first branch of the driver 104 (e.g., a voltage representation provided by the amplifier 244) is provided to the ADC 130. Conversely, responsive to P-N switch having a logical low value, the voltage representation of the second branch of the driver 104 is provided to the ADC 130.

The diagram 300 also includes a signal 302 representative of gate control signals of the transistor 202 and corresponding transistor of the amplifier 118. For example, the transistors are conductive in a forward direction responsive to the signal 302 having a logical high value and substantially non-conductive in the forward direction responsive to the signal 302 having a logical low value. The diagram 300 also includes a signal 304 representative of gate control signals of the transistor 204 and corresponding transistor of the amplifier 118. For example, the transistors are conductive in a forward direction responsive to the signal 304 having a logical high value and substantially non-conductive in the forward direction responsive to the signal 304 having a logical low value. In an example, the signals 302, 304 are logical inversions of each other.

The diagram 300 also includes a signal 306 representative of the current sum signal provided by the current summing circuit 114 and a signal 308 representative of the current sum signal provided by the current summing circuit 124. The diagram 300 also includes a signal 310 representative of an output of the switching circuit 128.

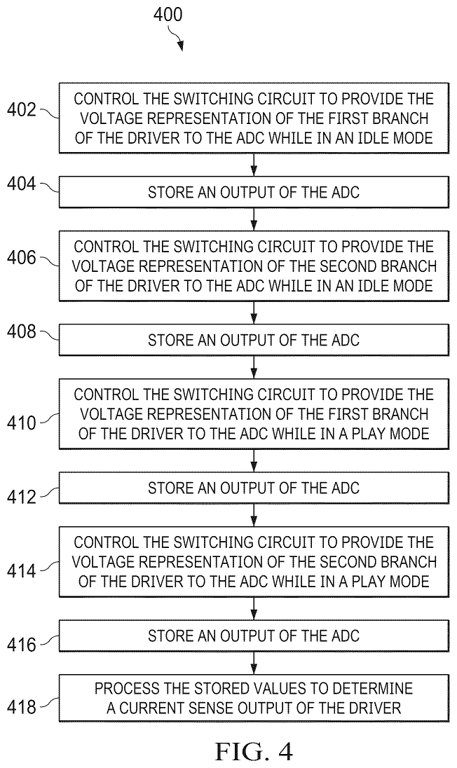

FIG. 4 is a flowchart of an example method 400 of current measurement in the system 100. In an example, the method 400 is implemented at least in part by the processor 102, such as by performing signal processing responsive to received signals, controlling the switching circuit 128, or the like.

At operation 402, the processor 102 controls the switching circuit 128 to provide the voltage representation of the first branch of the driver 104 to the ADC 130. In some examples, the processor controls the switching circuit 128 by providing a control signal to select an input corresponding to the first branch of the driver 104. The control signal may cause one or more switches to toggle states, may be a select signal of a multiplexer, or the like. In an example, the operation 402 is performed while the system 100 is in an idle mode (e.g., the driver 104 is not driving the output device 106 to provide an output).

At operation 404, the processor 102 stores an output of the ADC 130. In an example, the operation 404 is performed while the system 100 is in the idle mode.

At operation 406, the processor 102 controls the switching circuit 128 to provide the voltage representation of the second branch of the driver 104 to the ADC 130. In some examples, the processor controls the switching circuit 128 by providing a control signal to select an input corresponding to the second branch of the driver 104. The control signal may cause one or more switches to toggle states, may be a select signal of a multiplexer, or the like. In an example, the operation 406 is performed while the system 100 is in the idle mode.

At operation 408, the processor 102 stores an output of the ADC 130. In an example, the operation 408 is performed while the system 100 is in the idle mode.

At operation 410, the processor 102 controls the switching circuit 128 to provide the voltage representation of the first branch of the driver 104 to the ADC 130. In some examples, the processor controls the switching circuit 128 by providing a control signal to select the input corresponding to the first branch of the driver 104. The control signal may cause one or more switches to toggle states, may be a select signal of a multiplexer, or the like. In an example, the operation 402 is performed while the system 100 is in a play mode (e.g., the driver 104 is driving the output device 106 to provide an output).

At operation 412, the processor 102 stores an output of the ADC 130. In an example, the operation 412 is performed while the system 100 is in the play mode.

At operation 414, he processor 102 controls the switching circuit 128 to provide the voltage representation of the second branch of the driver 104 to the ADC 130. In some examples, the processor controls the switching circuit 128 by providing a control signal to select the input corresponding to the second branch of the driver 104. The control signal may cause one or more switches to toggle states, may be a select signal of a multiplexer, or the like. In an example, the operation 414 is performed while the system 100 is in the play mode.

At operation 416, the processor 102 stores an output of the ADC 130. In an example, the operation 416 is performed while the system 100 is in the play mode.

At operation 418, the processor 102 processes the stored values to determine a current sense output of the driver 104. For example, the processor 102 subtracts the value stored at operation 404 from the value stored at operation 412. The processor 102 next subtracts the value stored at operation 408 from the value stored at operation 414. The processor 102 subsequently adds the two resulting values to form the current sense output representative of current flow through the driver 104 (e.g., through the amplifier 108 and the amplifier 118).

Based on the determined current sense output representative of current flow through the driver 104, the processor 102 may take one or more actions. For example, as described above, the processor 102 determines DC and AC components of the current sense output. Based on these DC and AC components, the processor 102 determines whether a fault condition exists in the driver 104, such as an open load, a load short, a short to power, or a short to ground. For example, responsive to determining that the DC component of the current sense output exceeds a first threshold value, such as a negative threshold value, the processor 102 determines that a short to power fault exists in the driver 104. Similarly, responsive to determining that the DC component of the current sense output exceeds a second threshold value, such as a positive threshold value, the processor 102 determines that a short to ground fault exists in the driver 104. Yet still, responsive to determining that the AC component of the current sense output exceeds a third threshold value, the processor 102 determines that a load short fault exists in the driver 104. Responsive to determining that the AC component of the current sense output is less than a fourth threshold value, the processor 102 determines that an open load fault exists in the driver 104. Responsive to detecting the existence of a fault condition, the processor 102 may take one or more actions, such as controlling the driver 104 or any other component (which may not be shown) to mitigate the existence of the fault condition. In an example, responsive to detecting the existence of a fault condition, the processor 102 disables operation of the driver 104 (such as by de-asserting an enable signal of the driver 104). Responsive to detecting the existence of a fault condition, the processor 102 may also report the existence of the fault condition, such as by providing a control signal that causes a message to be transmitted, causes a visual indicator to become activated, or the like.

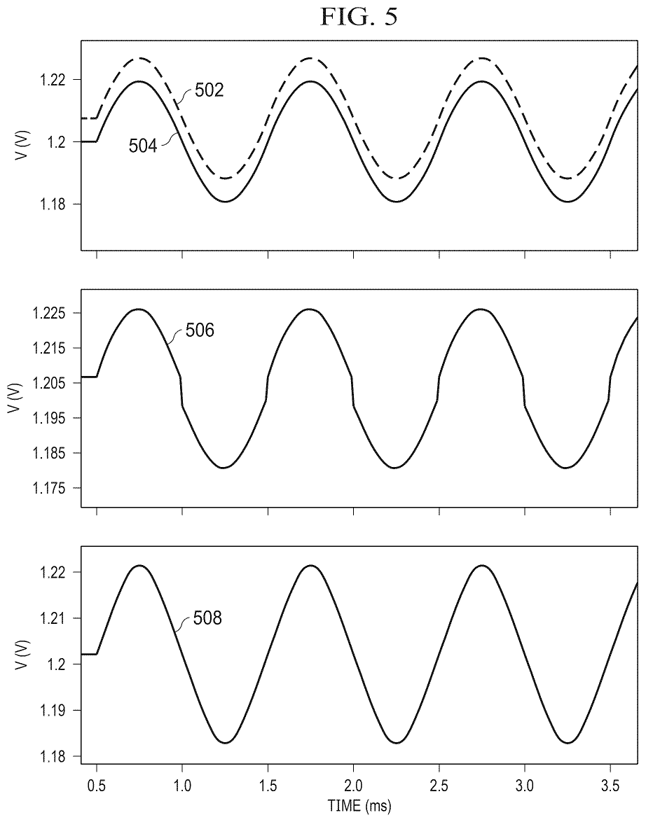

Also, the processor 102 may perform calibration for the driver 104. For example, if not calibrated, the output signal of the switching circuit 128 could include errors which could adversely affect performance of the driver 104 and/or fault detection performed by the processor 102, as described above. For example, in normal operation, the voltage representation of the current sum signal of the first branch of the driver 104 and the voltage representation of the current sum signal of the second branch of the driver 104 are substantially continuous in time. This is shown by signals 502 and 504, respectively, of FIG. 5. However, as shown by signal 506, which is representative of the switched output signal provided by the switching circuit 128 without offset calibration, a DC offset jump occurs in the switched output signal resulting from the switching action. Thus, processing performed by the processor 102 on the switched output signal may be distorted, resulting in erroneously determined values and unreliable results. As shown by the signal 508, which is representative of the switched output signal provided by the switching circuit 128 with offset calibration, the DC offset jump shown in signal 506 is largely mitigated in the switched output signal. In some examples, the processor 102 performs the calibration by storing the switched output signals resulting from the first branch of the driver 104 and the second branch of the driver 104 while the driver is not driving the output device 106 to produce an output, as described above, and subsequently subtracting these stored values from corresponding values of switched output signals resulting from the first branch of the driver 104 and the second branch of the driver 104 while the driver is driving the output device 106 to produce an output.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A circuit, comprising:
a first amplifier, comprising:
a first transistor having a control terminal and first and second terminals, the first terminal of the first transistor coupled to a first voltage terminal; and
a second transistor having a control terminal and first and second terminals, the first terminal of the second transistor coupled to the second terminal of the first transistor, and the second terminal of the second transistor coupled to a second voltage terminal;
a current sensing circuit having first, second, third, and fourth inputs, and having first, second, third, and fourth outputs, the first input of the current sensing circuit coupled to the first terminal of the first transistor, the second input of the current sensing circuit coupled to the control terminal of the first transistor, the third input of the current sensing circuit coupled to the control terminal of the second transistor, and the fourth input of the current sensing circuit coupled to the second voltage terminal;
a current measurement circuit having first, second, third, fourth, fifth, and sixth inputs and having first and second outputs, the first input of the current measurement circuit coupled to the first output of the current sensing circuit, the second input of the current measurement circuit coupled to the second output of the current sensing circuit, the third input of the current measurement circuit coupled to the third output of the current sensing circuit, and the fourth input of the current measurement circuit coupled to the fourth output of the current sensing circuit;
a current summing circuit having first, second, third, and fourth inputs and having first, second, and third outputs, the first input of the current summing circuit coupled to a third voltage terminal, the second input of the current summing circuit coupled to the second voltage terminal, the third input of the current summing circuit coupled to the first output of the current measurement circuit, the fourth input of the current summing circuit coupled to the second output of the current measurement circuit, the first output of the current summing circuit coupled to the fifth input of the current measurement circuit, and the second output of the current summing circuit coupled to the sixth input of the current measurement circuit; and
a converter circuit having first and second inputs and an output, the first input of the converter circuit coupled to a reference voltage terminal, and the second input of the converter circuit coupled to the third output of the current summing circuit.

2. The circuit of claim 1, wherein the current sensing circuit comprises:
a first resistor having a first terminal and a second terminal, the first terminal of the first resistor coupled to the first voltage terminal and the first output of the current sensing circuit and the second terminal of the first resistor coupled to the second output of the current sensing circuit;
a third transistor having a control terminal and first and second terminals, the first terminal of the third transistor coupled to the second terminal of the first resistor, the second terminal of the third transistor coupled to the second terminal of the first transistor and to a fifth output of the current sensing circuit, and the control terminal of the third transistor coupled to the control terminal of the first transistor;
a fourth transistor having a control terminal and first and second terminals, the first terminal of the fourth transistor coupled to the second terminal of the third transistor, and the control terminal of the fourth transistor coupled to the control terminal of the second transistor; and
a second resistor having a first terminal and a second terminal, the first terminal of the second resistor coupled to the second terminal of the fourth transistor and the third output of the current sensing circuit, and the second terminal of the second resistor coupled to the second voltage terminal and to the fourth output of the current sensing circuit.

3. The circuit of claim 1, wherein the current measurement circuit comprises:
a first current source having first and second terminals, the first terminal of the first current source coupled to a third voltage terminal;
a first resistor having first and second terminals, the first terminal of the first resistor coupled to the third output of the current sensing circuit;
a second resistor having first and second terminals, the first terminal of the second resistor coupled to the fourth output of the current sensing circuit;
a second amplifier having first and second inputs and an output, the first input of the second amplifier coupled to the second terminal of the first resistor and to the second terminal of the first current source, the second input of the second amplifier coupled to the second terminal of the second resistor and to the first output of the current summing circuit, and the output of the second amplifier coupled to the third input of the current summing circuit;
a third resistor having first and second terminals, the first terminal of the third resistor coupled to the first output of the current sensing circuit;
a fourth resistor having first and second terminals, the first terminal of the fourth resistor coupled to the second output of the current sensing circuit;
a third amplifier having first and second inputs and an output, the first input of the third amplifier coupled to the second terminal of the third resistor and to the second output of the current summing circuit, the second input of the third amplifier coupled to the second terminal of the fourth resistor, and the output of the third amplifier coupled to the fourth input of the current summing circuit; and
a second current source having first and second terminals, the first terminal of the second current source coupled to the second input of the third amplifier, and the second terminal of the second current source coupled to the second voltage terminal.

4. The circuit of claim 1, wherein the current summing circuit comprises:
a third transistor having a control terminal and first and second terminals, the first terminal of the third transistor coupled to the third voltage terminal;
a fourth transistor having a control terminal and first and second terminals, the first terminal of the fourth transistor coupled to the second terminal of the third transistor, the second terminal of the fourth transistor coupled to the fifth input of the current measurement circuit, and the control terminal of the fourth transistor coupled to the first output of the current measurement circuit;
a fifth transistor having a control terminal and first and second terminals, the first terminal of the fifth transistor coupled to the sixth input of the current measurement circuit, and the control terminal of the fifth transistor coupled to the second output of the current measurement circuit;
a sixth transistor having a control terminal and first and second terminals, the first terminal of the sixth transistor coupled to the second terminal of the fifth transistor, and the second terminal of the sixth transistor coupled to the second voltage terminal;
a seventh transistor having a control terminal and first and second terminals, the first terminal of the seventh transistor coupled to the third voltage terminal, and the control terminal of the seventh transistor coupled to the control terminal of the third transistor;
an eighth transistor having a control terminal and first and second terminals, the first terminal of the eighth transistor coupled to the second terminal of the seventh transistor, the second terminal of the eighth transistor coupled to the third output of the current summing circuit, and the control terminal of the eighth transistor coupled to the control terminal of the fourth transistor;
a ninth transistor having a control terminal and first and second terminals, the first terminal of the ninth transistor coupled to the third output of the current summing circuit, and the control terminal of the ninth transistor coupled to the control terminal of the fifth transistor; and
a tenth transistor having a control terminal and first and second terminals, the first terminal of the tenth transistor coupled to the second terminal of the ninth transistor, the second terminal of the tenth transistor coupled to the second voltage terminal, and the control terminal of the tenth transistor coupled to the control terminal of the fifth transistor.

5. The circuit of claim 1, wherein the converter circuit comprises:
a third amplifier having first and second inputs and an output, the first input of the third amplifier being the first input of the converter circuit, the second input of the third amplifier coupled to the third output of the current summing circuit, and the output of the third amplifier being the output of the converter circuit;
a resistor having first and second terminals, the first terminal of the resistor coupled to the output of the third amplifier and the second terminal of the resistor coupled to the second input of the third amplifier; and
a capacitor having first and second terminals, the first terminal of the capacitor coupled to the output of the third amplifier and the second terminal of the capacitor coupled to the second input of the third amplifier.

6. The circuit of claim 1, further comprising:
a switching circuit having first and second inputs and an output, the first input of the switching circuit coupled to the output of the converter circuit;
an analog-to-digital converter (ADC) having an input and an output, the input of the ADC coupled to the output of the switching circuit; and
a processor having an input, the input of the processor coupled to the output of the ADC.

7. The circuit of claim 6, further comprising
a second amplifier, comprising:
a third transistor having a control terminal and first and second terminals, the first terminal of the third transistor coupled to the first voltage terminal; and
a fourth transistor having a control terminal and first and second terminals, the first terminal of the fourth transistor coupled to the second terminal of the third transistor, and the second terminal of the fourth transistor coupled to the second voltage terminal;
a second current sensing circuit having first, second, third, and fourth inputs, and having first, second, third, and fourth outputs, the first input of the second current sensing circuit coupled to the first terminal of the third transistor, the second input of the second current sensing circuit coupled to the control terminal of the third transistor, the third input of the second current sensing circuit coupled to the control terminal of the fourth transistor, and the fourth input of the second current sensing circuit coupled to the second voltage terminal;
a second current measurement circuit having first, second, third, fourth, fifth, and sixth inputs and having first and second outputs, the first input of the second current measurement circuit coupled to the first output of the second current sensing circuit, the second input of the second current measurement circuit coupled to the second output of the second current sensing circuit, the third input of the second current measurement circuit coupled to the third output of the second current sensing circuit, and the fourth input of the second current measurement circuit coupled to the fourth output of the second current sensing circuit;
a second current summing circuit having first, second, third, and fourth inputs and having first, second, and third outputs, the first input of the second current summing circuit coupled to the third voltage terminal, the second input of the second current summing circuit coupled to the second voltage terminal, the third input of the second current summing circuit coupled to the first output of the second current measurement circuit, the fourth input of the second current summing circuit coupled to the second output of the second current measurement circuit, the first output of the second current summing circuit coupled to the fifth input of the second current measurement circuit, and the second output of the second current summing circuit coupled to the sixth input of the second current measurement circuit; and
a second converter circuit having first and second inputs and an output, the first input of the second converter circuit coupled to the reference voltage terminal, the second input of the second converter circuit coupled to the third output of the second current summing circuit, and the output of the second converter circuit coupled to the second input of the switching circuit.

8. A circuit, comprising:
a class-D amplifier configured to receive an input signal and provide a drive signal based on and responsive to the input signal for driving an output device;
a current sensing circuit coupled to the class-D amplifier and configured to provide first, second, third, and fourth voltage signals representative of current flow through the class-D amplifier;
a current measurement circuit coupled to the current sensing circuit and configured to provide a first voltage difference signal derived from the first and second voltage signals and a second voltage difference signal derived from the third and fourth voltage signals;
a current summing circuit coupled to the current measurement circuit and configured to determine a first current signal representative of the first voltage difference signal, determine a second current signal representative of the second voltage difference signal, and combine the first and second current signals to form a current sum signal; and
a converter circuit coupled to the current summing circuit and configured to convert the current sum signal to a voltage representation.

9. The circuit of claim 8, wherein the class-D amplifier has first and second control terminals, first and second input terminals, and an output, and wherein the current sensing circuit comprises:
a second class-D amplifier having first and second control terminals, first and second input terminals, and an output, the first control terminal of the second class-D amplifier coupled to the first control terminal of the class-D amplifier, the second control terminal of the second class-D amplifier coupled to the second control terminal of the class-D amplifier, and the output of the second class-D amplifier coupled to the output of the class-D amplifier;
a first resistor having first and second terminals, the first terminal of the first resistor coupled to the first input terminal of the class-D amplifier and the second terminal of the first resistor coupled to the first input of the second class-D amplifier; and
a second resistor having first and second terminals, the first terminal of the second resistor coupled to the second input of the second class-D amplifier, and the second terminal of the second resistor coupled to the second input of the class-D amplifier.

10. The circuit of claim 8, wherein the current measurement circuit comprises:
a first current source having first and second terminals, the first terminal of the first current source coupled to a voltage terminal;
a first resistor having first and second terminals, the first terminal of the first resistor coupled to the current sensing circuit to receive the third voltage signal;
a second resistor having first and second terminals, the first terminal of the second resistor coupled to the current sensing circuit to receive the fourth voltage signal;
a second amplifier having first and second inputs and an output, the first input of the second amplifier coupled to the second terminal of the first resistor and to the second terminal of the first current source, the second input of the second amplifier coupled to the second terminal of the second resistor and to a first output of the current summing circuit, and the output of the second amplifier coupled to the current summing circuit to provide the first voltage difference signal;
a third resistor having first and second terminals, the first terminal of the third resistor coupled to the current sensing circuit to receive the first voltage signal;
a fourth resistor having first and second terminals, the first terminal of the fourth resistor coupled to the current sensing circuit to receive the second voltage signal;
a third amplifier having first and second inputs and an output, the first input of the third amplifier coupled to the second terminal of the third resistor and to a second output of the current summing circuit, the second input of the third amplifier coupled to the second terminal of the fourth resistor, and the output of the third amplifier coupled to the current summing circuit to provide the second voltage difference signal; and
a second current source having first and second terminals, the first terminal of the second current source coupled to the second input of the third amplifier, and the second terminal of the second current source coupled to a ground terminal.

11. The circuit of claim 8, wherein the current summing circuit comprises:
a first transistor having a control terminal and first and second terminals, the first terminal of the first transistor coupled to a voltage terminal, the second terminal of the first transistor coupled to the current measurement circuit to provide the first current signal, and the control terminal coupled to the current measurement circuit to receive the first voltage difference signal; and
a second transistor having a control terminal and first and second terminals, the first terminal of the second transistor coupled to the current measurement circuit to provide the second current signal, the second terminal of the second transistor coupled to a ground terminal, and the control terminal of the first transistor coupled to the current measurement circuit to receive the second voltage difference signal;
a third transistor having a control terminal and first and second terminals, the first terminal of the third transistor coupled to the first terminal of the first transistor, the second terminal of the third transistor coupled to the converter circuit to provide the current sum signal, and the control terminal of the third transistor coupled to the control terminal of the first transistor; and
a fourth transistor having a control terminal and first and second terminals, the first terminal of the fourth transistor coupled to the second terminal of the third transistor, the second terminal of the fourth transistor coupled to the ground terminal, and the control terminal of the fourth transistor coupled to the control terminal of the second transistor.

12. The circuit of claim 8, wherein the converter circuit comprises:
an amplifier having first and second inputs and an output, the first input of the amplifier coupled to a reference voltage terminal, and the second input of the amplifier coupled to the current summing circuit to receive the current sum signal;
a resistor having first and second terminals, the first terminal of the resistor coupled to the output of the amplifier and the second terminal of the resistor coupled to the second input of the amplifier; and
a capacitor having first and second terminals, the first terminal of the capacitor coupled to the output of the amplifier and the second terminal of the capacitor coupled to the second input of the amplifier.

13. The circuit of claim 8, further comprising:
a switching circuit having first and second inputs and an output, the first input of the switching circuit coupled to the output of the converter circuit, wherein the switching circuit is configured to selectively provide the voltage representation of the current sum signal as a switched output signal of the switching circuit; and
an analog-to-digital converter (ADC) having an input and an output, the input of the ADC coupled to the output of the switching circuit, wherein the ADC wherein the ADC is configured to receive the switched output signal and provide a digital representation of the switched output signal.

14. The circuit of claim 13, further comprising a processor coupled to the ADC, the processor configured to:
receive the digital representation of the switched output signal;
determine, at a first time at which the circuit is not driving the output device, a first value of the digital representation of the switched output signal;
determine, at a second time at which the circuit is driving the output device, a second value of the digital representation of the switched output signal;
determine, based on the first and second values, an estimated value of current flowing through the class-D amplifier; and
control the circuit based on the estimated value of current flowing through the class-D amplifier.

15. The circuit of claim 14, wherein the processor is coupled to the switching circuit and configured to control switching of the switching circuit to select from among multiple input signal sources of the switching circuit for providing the switched output signal.

16. A system, comprising:
an output device; and
a driver, comprising a first branch, comprising:
an amplifier configured to receive an input signal and provide a drive signal based on and responsive to the input signal for driving the output device;
a current sensing circuit coupled to the amplifier and configured to provide first, second, third, and fourth voltage signals representative of current flow through the amplifier;
a current measurement circuit coupled to the current sensing circuit and configured to provide a first voltage difference signal derived from the first and second voltage signals and a second voltage difference signal derived from the third and fourth voltage signals;
a current summing circuit coupled to the current measurement circuit and configured to determine a first current signal representative of the first voltage difference signal, determine a second current signal representative of the second voltage difference signal, and combine the first and second current signals to form a current sum signal; and
a converter circuit coupled to the current summing circuit and configured to convert the current sum signal to a voltage representation.

17. The system of claim 16, further comprising a filter coupled to the amplifier and configured to receive the drive signal from the amplifier and drive the output device based on the drive signal.

18. The system of claim 16, wherein the driver comprises a second branch configured to provide a second voltage representation of a second current sum signal.

19. The system of claim 16, wherein the driver comprises:
a switching circuit having first and second inputs and an output, the first input of the switching circuit coupled to the output of the converter circuit and the second input of the switching circuit coupled to the second branch, wherein the switching circuit is configured to selectively provide the voltage representation of the current sum signal or the second voltage representation of the second current sum signal as a switched output signal of the switching circuit; and
an analog-to-digital converter (ADC) having an input and an output, the input of the ADC coupled to the output of the switching circuit, wherein the ADC wherein the ADC is configured to receive the switched output signal and provide a digital representation of the switched output signal.

20. The system of claim 19, further comprising a processor coupled to the ADC, the processor configured to:
receive the digital representation of the switched output signal;
determine, at a first time at which the driver is not driving the output device, a first value of the digital representation of the switched output signal;
determine, at a second time at which the driver is driving the output device, a second value of the digital representation of the switched output signal;
determine, based on the first and second values, an estimated value of current flowing through the amplifier; and
control the system based on the estimated value of current flowing through the amplifier.
